(19) United States
(12) Patent Application Publication
(10) Pub. No.: US 2026/0221984 A1
(43) Pub. Date: Jul. 30, 2026

(54) ANALOG-TO-DIGITAL CONVERSION CIRCUT, ELECTRONIC DEVICE, AND OPERATION METHOD

(71) Applicant: TSINGHUA UNIVERSITY, Beijing (CN)

(72) Inventors: Huaqiang WU, Beijing (CN); Qiumeng WEI, Beijing (CN); Lu JIE, Beijing (CN); Dong WU, Beijing (CN); Peng YAO, Beijing (CN); Sining PAN, Beijing (CN); Bin GAO, Beijing (CN); He QIAN, Beijing (CN)

(73) Assignee: TSINGHUA UNIVERSITY, Beijing (CN)

(21) Appl. No.: 19/144,380

(22) PCT Filed: May 10, 2023
(86) PCT No.: PCT/CN2023/093192

§ 371 Date: Jun. 27, 2025

(30) Foreign Application Priority Data
Dec. 27, 2022 (CN) 202211684779.4

(51) Int. Cl. H03M 1/46; G11C 13/00

(52) U.S. Cl. CPC H03M 1/46; G11C 13/003; G11C 2213/79

(57) ABSTRACT

An analog-to-digital conversion circuit, an electronic apparatus, and an operation method are provided. The analog-to-digital conversion circuit includes: An analog-to-digital conversion circuit, including: a clamping module, coupled to a load circuit through a clamping point, where the load circuit provides a load current during working; a bias current generation module, coupled to the clamping module through the clamping point and configured to provide a bias current to the clamping point; and a quantization module, coupled to the clamping module through the clamping point and a first node, configured to provide a bias voltage to the clamping module through the first node to obtain a clamping branch current that is input into the clamping point, and further configured to provide a first current to the clamping point and regulate the first current based on a comparison result of the bias current and the clamping branch current to quantize the load current.

### CROSS REFERENCE TO RELATED APPLICATIONS

The present disclosure is a U.S. national stage application of International Patent Application No. PCT/CN2023/093192, filed on May 10, 2023, which claims priority of the Chinese Patent Application No. 202211684779.4, filed on Dec. 27, 2022. All the aforementioned patent applications are hereby incorporated by reference in their entireties.

### TECHNICAL FIELD

Embodiments of the present disclosure relate to an analog-to-digital conversion circuit, an electronic apparatus, and an operation method.

### BACKGROUND

In recent years, analog Computing In Memory (CIM) based on a resistive memory unit array has shown great potential in the implementation of energy-efficient neural network hardware acceleration. Network weights are stored based on a non-volatile regulatable conductance of a device, a matrix vector multiplication result represented by an analog current value may be obtained after a voltage pulse representing an input numerical value is applied. In order to effectively utilize the high parallelism of the analog CIM and the high flexibility of digital logic, the resistive memory unit array needs to be equipped with a large number of analog-to-digital converters (ADCs) to quantize current results; and a conversion speed and precision of the ADC directly affect a throughput rate and accuracy of array parallel computing, namely, the performance of the ADC determines the function and computing power of a CIM system.

### SUMMARY

Embodiments of the present disclosure provide an analog-to-digital conversion circuit, including: a clamping module, coupled to a load circuit through a clamping point, in which the load circuit provides a load current during working; a bias current generation module, coupled to the clamping module through the clamping point and configured to provide a bias current to the clamping point; and a quantization module, coupled to the clamping module through the clamping point and a first node, configured to provide a bias voltage to the clamping module through the first node to obtain a clamping branch current that is input into the clamping point, and further configured to provide a first current to the clamping point and regulate the first current based on a comparison result of the bias current and the clamping branch current to quantize the load current.

For example, in the analog-to-digital conversion circuit provided by at least one embodiment of the present disclosure, the clamping module is further configured to receive a clamping reference voltage from a second node, and the quantization module is further configured to regulate the first current to reduce an offset between a voltage at the clamping point and the clamping reference voltage.

For example, in the analog-to-digital conversion circuit provided by at least one embodiment of the present disclosure, the clamping module includes an amplifier unit and a clamping tube unit, a first input terminal of the amplifier unit is coupled to the second node, and a second input terminal of the amplifier unit is coupled to the clamping point; and a control terminal of the clamping tube unit is coupled to an output terminal of the amplifier unit, a first terminal of the clamping tube unit is coupled to the first node, and a second terminal of the clamping tube unit is coupled to the clamping point.

For example, in the analog-to-digital conversion circuit provided by at least one embodiment of the present disclosure, the quantization module includes a first current generation unit and a control unit, the first current generation unit is configured to generate the first current that is quantized, and the control unit is configured to control the first current generation unit to increase the first current or decrease the first current based on the comparison result of the bias current and the clamping branch current.

For example, in the analog-to-digital conversion circuit provided by at least one embodiment of the present disclosure, the control unit includes a comparison subunit and a regulation subunit, the comparison subunit is configured to provide the bias voltage to the clamping module through the first node to obtain the clamping branch current that is input into the clamping point, and further configured to convert the clamping branch current into a first differential voltage and a second differential voltage, and output a comparison result of the first differential voltage and the second differential voltage; and the regulation subunit is configured to determine the comparison result of the bias current and the clamping branch current based on the comparison result of the first differential voltage and the second differential voltage, and to generate a logic signal based on the comparison result of the bias current and the clamping branch current.

For example, in the analog-to-digital conversion circuit provided by at least one embodiment of the present disclosure, the first current generation unit is further configured to increase the first current or decrease the first current based on the logic signal.

For example, in the analog-to-digital conversion circuit provided by at least one embodiment of the present disclosure, the comparison subunit includes a cancellation current source, and the cancellation current source is configured to generate a cancellation current, in which the cancellation current is equal to the bias current.

For example, in the analog-to-digital conversion circuit provided by at least one embodiment of the present disclosure, the regulation subunit is a successive approximation register.

For example, in the analog-to-digital conversion circuit provided by at least one embodiment of the present disclosure, the first current generation unit is a current-mode analog-to-digital converter.

For example, the analog-to-digital conversion circuit provided by at least one embodiment of the present disclosure further including a second bias current generation module, in which the second bias current generation module is coupled to the clamping module through a third node and configured to generate a second bias current; and the quantization module is further coupled to the clamping module through the third node, configured to provide a second clamping branch current to the third node, and further configured to provide a second current to the third node and regulate the second current based on the second bias current and the comparison result of the bias current and the clamping branch current.

For example, in the analog-to-digital conversion circuit provided by at least one embodiment of the present disclosure, the clamping module includes a second clamping tube unit and an amplifier unit, and a control terminal of the second clamping tube unit is coupled to an output terminal of the amplifier unit, a first terminal of the second clamping tube unit is coupled to the first node, and a second terminal of the second clamping tube unit is coupled to the third node.

For example, in the analog-to-digital conversion circuit provided by at least one embodiment of the present disclosure, the quantization module includes a second current generation unit and a control unit, the second current generation unit is configured to generate the second current, the control unit is configured to control the second current generation unit to increase the second current or decrease the second current based on the second bias current and the comparison result of the bias current and the clamping branch current.

For example, in the analog-to-digital conversion circuit provided by at least one embodiment of the present disclosure, the load circuit includes a first source line, N resistive devices and N bit lines, N first terminals of the N resistive devices are respectively connected to the first source line through N connection positions on the first source line, and N second terminals of the N resistive devices are respectively connected to the N bit lines, the clamping module is coupled to an Nth connection position in the N connection positions through the clamping point, and

the quantization module is coupled to an ith connection position in the N connection positions, and configured to provide the first current at the ith connection position, and regulate the first current based on a current on an ith bit line in the N bit lines and the load current to enable a load current that is regulated to be equal to 0, where N is an integer greater than 1, i=1, 2, . . . . N.

At least one embodiment of the present disclosure further provides an electronic apparatus, including the analog-to-digital conversion circuit provided by any embodiment of the present disclosure.

For example, the electronic apparatus provided by at least one embodiment of the present disclosure further includes a voltage supply module and the load circuit, in which the voltage supply module is configured to provide a clamping reference voltage to the clamping module through the second node.

For example, in the electronic apparatus provided by at least one embodiment of the present disclosure, the load circuit is a memristor unit array.

At least one embodiment of the present disclosure further provides an operation method of the analog-to-digital conversion circuit provided by at least one embodiment of the present disclosure, including: providing the bias current to the clamping point; providing the bias voltage to the clamping module to obtain the clamping branch current that is input into the clamping point; providing the first current to the clamping point; and regulating the first current based on the comparison result of the bias current and the clamping branch current to quantize the load current.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1A is a schematic diagram of a buffer clamping circuit;

FIG. 1B is a schematic diagram of a circuit structure of an analog Computing In Memory array;

FIG. 2 is a schematic block diagram of an analog-to-digital conversion circuit provided by at least one embodiment of the present disclosure;

FIG. 3 is a schematic diagram of one example of the analog-to-digital conversion circuit provided by at least one embodiment of the present disclosure;

FIG. 4A is a schematic diagram of successive approximation current regulation provided by at least one embodiment of the present disclosure;

FIG. 4B is a schematic diagram of successive approximation voltage regulation provided by at least one embodiment of the present disclosure;

FIG. 5A is a schematic diagram of one example of a clamping module provided by at least one embodiment of the present disclosure;

FIG. 5B is a schematic diagram of another example of the clamping module provided by at least one embodiment of the present disclosure;

FIG. 5C is a schematic diagram of yet another example of the clamping module provided by at least one embodiment of the present disclosure;

FIG. 6 is a schematic diagram of one example of the effect of parasitic capacitance on current distribution of the analog-to-digital conversion circuit provided by at least one embodiment of the present disclosure;

FIG. 7A is a schematic diagram of one example of a comparison subunit provided by at least one embodiment of the present disclosure;

FIG. 7B is a schematic diagram of another example of the comparison subunit provided by at least one embodiment of the present disclosure;

FIG. 7C is a schematic diagram of yet another example of the comparison subunit provided by at least one embodiment of the present disclosure;

FIG. 7D is a schematic diagram of still yet another example of the comparison subunit provided by at least one embodiment of the present disclosure;

FIG. 8 is another schematic block diagram of the analog-to-digital conversion circuit provided by at least one embodiment of the present disclosure;

FIG. 9 is a schematic diagram of another specific example of the analog-to-digital conversion circuit provided by at least one embodiment of the present disclosure;

FIG. 10 is a schematic diagram of yet another example of the analog-to-digital conversion circuit provided by at least one embodiment of the present disclosure;

FIG. 11A is a schematic diagram of one example of the analog-to-digital conversion circuit used for decreasing a clamping error of a load circuit provided by at least one embodiment of the present disclosure;

FIG. 11B is a schematic diagram of one example of current distribution of the analog-to-digital conversion circuit when used for decreasing the clamping error of the load circuit provided by at least one embodiment of the present disclosure;

FIG. 12 is a schematic diagram of an electronic apparatus provided by at least one embodiment of the present disclosure; and

FIG. 13 is a flowchart of an operation method of the analog-to-digital conversion circuit provided by at least one embodiment of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

The present disclosure is described below through several specific embodiments. In order to keep the following description of the embodiments of the present disclosure clear and concise, detailed descriptions of known functions and components may be omitted. When any component of the embodiments of the present disclosure appears in more than one of the drawings, the component is indicated by the same or similar reference mark in each of the drawings.

In addition to needing to quantize input current, an analog-to-digital converter (ADC) used for a current domain of analog Computing In Memory (CIM) also needs to perform accurate voltage clamping on a memristor array for the analog CIM. Since the accuracy and speed of clamping and sampling directly affect the overall conversion speed and quantization accuracy of the ADC, a clamping circuit needs to provide sufficiently low equivalent output resistance and a sufficiently high bandwidth to achieve precise fast clamping. Therefore, a clamping and sampling module often needs to consume a large amount of power, which reduces the overall energy efficiency of a system, and becomes a main bottleneck of the performance of the current domain ADC of CIM.

In addition, in order to pursue the extreme computing power, the system for CIM needs to increase the scale of a CIM array to improve the parallelism of matrix-vector multiplication, but meanwhile, a higher instantaneous computing current is introduced, which brings about a higher wiring IR drop, causes a serious deviation of the current value of the array, and affects the computational accuracy. The array current does not decrease while a process node continuously shrinks, but the metal wiring resistance increases significantly, so that the problem of the wiring IR drop at the advanced process node is more serious. For this reason, the CIM array tends to reduce the wiring resistance by increasing the wiring width, so as to alleviate the effect of the wiring IR drop on the computational accuracy, but meanwhile, the parasitic capacitance of the array increases, thereby influencing the speed of the ADC.

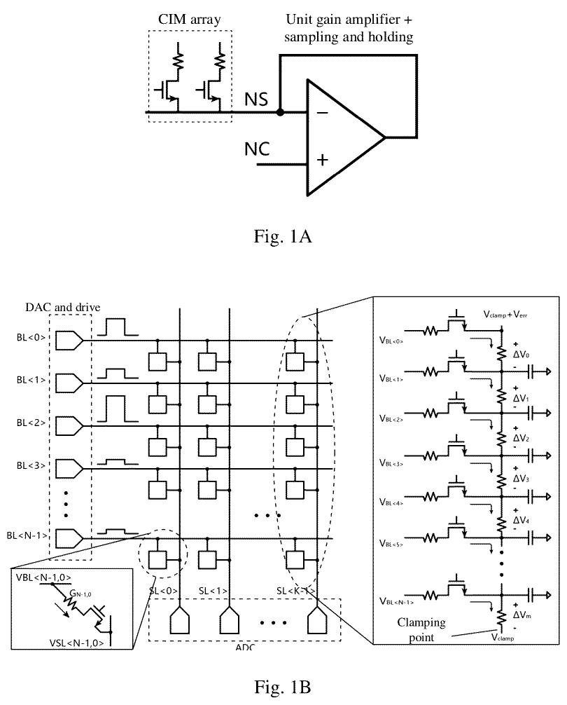

FIG. 1A is a schematic diagram of a buffer clamping circuit.

For example, as shown in FIG. 1A, the buffer clamping circuit may be used for the current domain ADC of the CIM array. In this buffer clamping circuit, a voltage V(NS) at an inverting input terminal NS of an amplifier is clamped to be consistent with a voltage V(NC) at a co-directional input terminal NC by connecting the amplifier into a unity gain buffer structure, so that the inverting input terminal NS becomes a virtual location. However, the unity gain buffer structure needs a higher amplifier gain to meet the required clamping accuracy, namely, the clamping accuracy and establishment speed cannot be decoupled; in addition, variations of the computing current in the CIM array directly affect the transconductance of a drive tube (not shown in the drawings) connected behind an output terminal of the amplifier, thereby making it difficult to maintain good stability and suppress noise.

FIG. 1B is a schematic diagram of a circuit structure of an analog Computing In Memory array.

For example, as shown in FIG. 1B, the analog Computing In Memory (CIM) array is formed by a plurality of memristor units which form an array of N rows and K columns, with N and K each being a positive integer. For example, the memristor unit may be a 1T1R unit, in which R represents the memristor (such as a resistive random access memory (RRAM) or other resistive devices) and T represents a switching element (such as a transistor or other three-terminal switch elements). In FIG. 1B, BL<0>, BL<1> . . . . BL<N−1> respectively represent bit lines of a first row, a second row . . . an Nth row, and the memristor in the memristor unit of each column is connected to the bit line corresponding to this column; and SL<0>, SL<1> . . . . SL<K−1> respectively represent source lines of a first column, a second column . . . a Kth column. For example, one memristor unit is bridged at the intersection of each row BL and each column SL, and the conductance thereof is represented as Gij, in which i=0, 1, . . . , N−1, and j=0, 1, . . . , K−1. A source of the switching element (for example, a source of the transistor) in the memristor unit of each column is connected to the source line SL corresponding to this row; and a control electrode of the switching element (for example, a gate electrode of the transistor) in the memristor unit of each column is connected to a word line WL corresponding to this row (not shown in the drawings). According to the Kirchhoff's law, by setting a state (such as a resistance value or conductance value) of the memristor unit and applying corresponding word line signals and bit line signals to the word line WL and the bit line BL, the above memristor array may complete the analog Computing In Memory in parallel.

For example, as shown in FIG. 1B, a digital-to-analog converter (DAC) and a voltage drive circuit provide an input pulse voltage to the BL of each row, and the amplitude thereof represents an input numerical value. The ADC for current quantization is connected to the SL of each column; and the ADC, while providing a stable clamping voltage to the SL, converts the collected current of the SL into a digital result output for subsequent processing by a computing unit, thereby completing the quantization.

For example, as shown in FIG. 1B, VBL<i, j> and VSL<i, j> are respectively local voltages of SL<j> and BL<i> at the intersection, and a relationship between the current I(SL<j>) on the SL and the input voltage of each row is approximately as shown in Formula (1):

$$I ( SL < j > ) = {\sum }_{1 = 0}^{N - 1} < ( {VBL}_{< i , j >} - {VSL}_{< i , j >} ) \times {G}_{i , j} . \qquad Formula ( 1 )$$

For example, in ideal circumstances, line resistance on the BL and the SL are infinitesimal, and the voltages on various parts of the BL<i> are equal, with VBL<i, j>=V(BL<i>), and similarly, the voltages on various parts of the SL<j> are all equal to the accurate clamping voltage V_{clamp}, with VSL<i, j>=V_{clamp}. However, there are distributed parasitic resistance and parasitic capacitance on the actual SL as shown on the right side of FIG. 1B, thereby resulting in a decrease in the computational accuracy and switching speed of the CIM array, with main effects and principles as follows:

1) the parasitic resistance causes the local voltage VSL<i, j> on the SL to be affected by the current distribution: for example, when the input voltage on the BL is higher than the clamping voltage on the SL, and the current converges on the SL and flows to the ADC, the wiring IR drop is generated on each part of the line resistance, so that the voltage of the top of the SL is the sum of the standard clamping voltage and the total wiring IR drop (V_{clamp}+Vₑᵣᵣ), namely, higher than the standard clamping voltage V_{clamp} at the bottom of the SL, and then the voltages ΔVi at two terminals of the memristor unit at different positions are offset from an ideal voltage value, thereby resulting in a deviation between the current actually flowing into the ADC and an ideal value, and reducing the computational accuracy; and

2) the parasitic capacitance affects the establishment speed of the clamping voltage: when a load on the SL is suddenly turned on, due to the limited bandwidth of the circuit for generating the clamping voltage, a certain establishment time is required to allow the fluctuating clamping voltage to return to the steady state, and then the accurate quantification can be performed; however, a large amount of parasitic capacitance in the CIM array reduces the bandwidth of a clamping loop, thereby severely reducing the quantization speed of the ADC.

In addition, when different SL current loads flow on the CIM array, there is a deviation between the clamping voltage and a set value under the no-load condition, thereby resulting in inaccurate clamping, and affecting the computational accuracy.

At least one embodiment of the present disclosure provides an analog-to-digital conversion (ADC) circuit, including a clamping module, a bias current generation module, and a quantization module. The clamping module is coupled to a load circuit through a clamping point, in which the load circuit provides a load current during work; the bias current generation module is coupled to the clamping module through the clamping point and configured to provide a bias current to the clamping point; and the quantization module is coupled to the clamping module through the clamping point and a first node, configured to provide a bias voltage to the clamping module through the first node to obtain a clamping branch current that is input into the clamping point, and further configured to provide a first current to the clamping point and regulate the first current based on a comparison result of the bias current and the clamping branch current to quantize the load current.

At least one embodiment of the present disclosure further provides an electronic apparatus corresponding to the above analog-to-digital conversion circuit.

At least one embodiment of the present disclosure further provides an operation method corresponding to the above analog-to-digital conversion circuit.

The analog-to-digital conversion circuit, the electronic apparatus, and the operation method provided by at least one embodiment of the present disclosure optimize an ADC circuit structure, and adopt a completely new clamping quantization mechanism based on the optimized ADC circuit structure, thereby improving the clamping accuracy by utilizing the quantization module and reducing the power consumption and area overhead of the ADC circuit, while achieving a high-speed and low-gain clamping function; in addition, the optimized ADC circuit structure may also be used for adaptively cancelling the computing current on the load circuit, thereby reducing the computing deviation caused by the wiring IR drop and decreasing the effect of parasitic parameters on the load circuit.

Some embodiments of the present disclosure will now be described in detail in conjunction with the accompanying drawings.

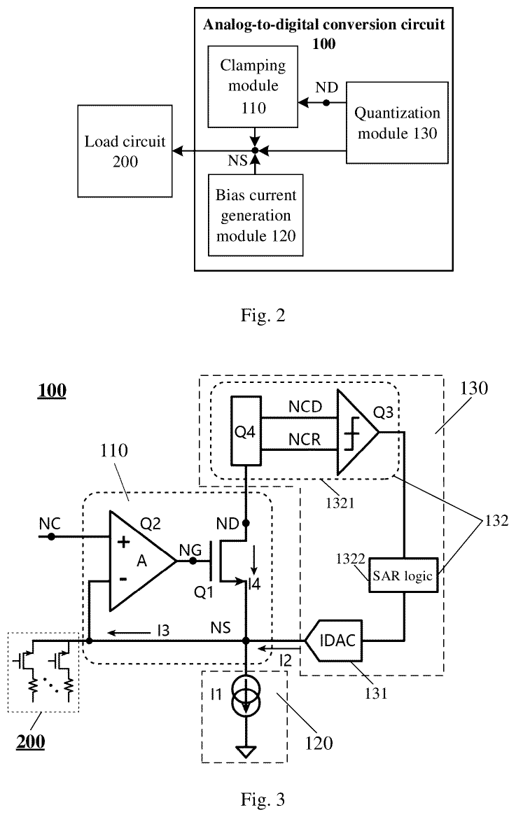

FIG. 2 is a schematic block diagram of an analog-to-digital conversion circuit provided by at least one embodiment of the present disclosure.

For example, as shown in FIG. 2, the analog-to-digital conversion circuit 100 includes a clamping module 110, a bias current generation module 120, and a quantization module 130. The clamping module 110 is coupled to a load circuit 200 through a clamping point NS, and the load circuit 200 provides a load current during work. The bias current generation module 120 is coupled to the clamping module through the clamping point NS and configured to provide a bias current to the clamping point NS. The quantization module 130 is coupled to the clamping module through the clamping point NS and a first node ND, configured to provide a bias voltage to the clamping module through the first node ND to obtain a clamping branch current that is input into the clamping point NS, and further configured to provide a first current to the clamping point NS and regulate the first current based on a comparison result of the bias current and the clamping branch current to quantize the load current.

FIG. 3 is a schematic diagram of one example of the analog-to-digital conversion circuit provided by at least one embodiment of the present disclosure. For example, FIG. 3 shows a circuit structure of one specific implementation example of the analog-to-digital conversion circuit 100 shown in FIG. 2.

For example, as shown in FIG. 3, the load circuit 200 may be an analog Computing In Memory (CIM) array, and for example, may also be a memristor array of other types, which is not limited in the embodiment of the present disclosure. For example, by taking the load circuit 200 as the CIM array as shown in FIG. 1B for an example, the clamping module 110 is coupled to a first source line SL<j> in the load circuit 200 through the clamping point NS (for example, the first source line SL<j> is the jth source line in the K columns of source lines in FIG. 1B); and the load circuit 200 provides a load current I3 to the clamping point NS through the first source line SL<j> during work. For example, the clamping module 110 is further configured to receive a clamping reference voltage V(NC) from a second node NC.

For example, as shown in FIG. 3, the clamping module 110 includes an amplifier unit Q2 and a clamping tube unit Q1. For example, a first input terminal of the amplifier unit Q2 is coupled to the second node NC, and a second input terminal of the amplifier unit Q2 is coupled to the clamping point NS; and a control terminal of the clamping tube unit Q1 is coupled to an output terminal of the amplifier unit Q2, a first terminal of the clamping tube unit Q1 is coupled to the first node ND, and a second terminal of the clamping tube unit Q1 is coupled to the clamping point NS.

For example, the clamping module 110 is a source-follower structure consisting of the amplifier unit Q2 and the clamping tube unit Q1. For example, the clamping tube unit Q1 isolates the output terminal of the amplifier unit Q2 from the load circuit 200, and output resistance rₒ of the clamping module 110, as viewed from the clamping point NS, is approximately as shown in the following Formula (2):

$${r}_{o} = 1 / ( A \times {g}_{m} ) \qquad Formula ( 2 )$$

in which gₘ is transconductance of the clamping tube unit Q1, and A is gain of the amplifier unit Q2. By increasing the gain A and the transconductance gₘ, the clamping accuracy and establishment speed may be improved simultaneously, so that the high-speed and low-gain clamping function may be achieved.

For example, as shown in FIG. 3, the amplifier unit Q2 may be an operational amplifier, with a first input terminal being a co-directional input terminal of the operational amplifier, a second input terminal being an inverting input terminal of the operational amplifier, and an output terminal being an output terminal of the operational amplifier; and the clamping tube unit Q1 may be an N-type transistor, with a first terminal which may be a collector of the transistor, a second terminal which may be an emitter of the transistor, and a control terminal which may be a base of the transistor. For example, the clamping tube unit may also be electronic elements of other types, such as a metal-oxide semiconductor field effect transistor (MOSFET), a thin film transistor, or other three-terminal switch elements. For example, when the amplifier unit or the clamping tube unit is the electronic elements of other types, other connection manners may also be selected according to actual situations, and the types of the amplifier and the clamping tube and the connection manners thereof are not limited in the embodiment of the present disclosure. Further, the circuit structure of the clamping module 110 as shown in FIG. 3 is merely one example, and circuit structures of other types may also be selected for the clamping module according to actual needs, which is not limited in the embodiment of the present disclosure.

For example, as shown in FIG. 3, the bias current generation module 120 is coupled to the clamping module 110 through the clamping point NS and configured to provide a bias current I1 to the clamping point NS. For example, the bias current generation module 120 may be a current source or other electronic elements capable of providing bias currents, which is not limited in the embodiment of the present disclosure.

For example, as shown in FIG. 3, the quantization module 130 provides a bias voltage V(ND) to the clamping module 110 through the first node ND to obtain a clamping branch current I4 that is input into the clamping point NS; in addition, the quantization module 130 provides a first current I2 to the clamping point NS, and decreases the offset between the voltage V(NS) at the clamping point NS and the clamping reference voltage V(NC) by regulating the first current I2. For example, the quantization module 130 may compare the bias current I1 with the clamping branch current I4, and regulate the first current I2 based on a comparison result to quantize the load current I3.

For example, as shown in FIG. 3, the quantization module 130 includes a first current generation unit 131 and a control unit 132. The first current generation unit 131 is configured to generate a quantized first current I2, and the control unit 132 is configured to control the first current generation unit 131 to increase the first current I2 or decrease the first current I2 based on the comparison result of the bias current I1 and the clamping branch current I4.

It should be noted that the first current generation unit 131 may be a current-mode digital-to-analog converter (IDAC) as shown in FIG. 3, and may also be other electronic elements capable of generating and regulating the first current I2, which is not limited in the embodiment of the present disclosure.

For example, as shown in FIG. 3, the control unit 132 includes a comparison subunit 1321 and a regulation subunit 1322. For example, the comparison subunit 1321 is configured to provide a bias voltage V(ND) to the clamping module 110 through the first node ND to obtain a clamping branch current I4 that is input into the clamping point NS, and further configured to convert the clamping branch current I4 into a first differential voltage V(NCD) and a second differential voltage V(NCR) and output a comparison result of the first differential voltage V(NCD) and the second differential voltage V(NCR).

For example, the regulation subunit 1322 is configured to determine the comparison result of the bias current I1 and the clamping branch current I4 based on the comparison result of the first differential voltage V(NCD) and the second differential voltage V(NCR), and generate a logic signal based on the comparison result of the bias current I1 and the clamping branch current I4. For example, the first current generation unit 131 is further configured to increase the first current I2 or decrease the first current I2 based on the logic signal.

For example, the comparison result of the bias current I1 and the clamping branch current I4 is determined based on the comparison result of the first differential voltage V(NCD) and the second differential voltage V(NCR) as shown in the following Formula (3):

$$\{ \begin{matrix}V ( NCD ) < V ( NCR ) , I 4 > I 1 \\ V ( NCD ) > V ( NCR ) , I 4 < I 1\end{matrix} . \qquad Formula ( 3 )$$

For example, the regulation subunit 1322 obtains the comparison result of the bias current I1 and the clamping branch current I4 according to the comparison result of the differential voltages output by the comparison subunit 1321, so as to generate the logic signal; and the first current generation unit 131 may regulate the first current I2 based on the logic signal: if I4>I1, the first current I2 is increased, otherwise the first current I2 is decreased. For example, by regulating the first current I2 in the manner described above, the quantization of the load current I3 may be achieved.

It should be noted that the quantization module 130 shown in FIG. 3 is merely one example. Firstly, the quantization module 130 may be a loop formed by the first current generation unit 131 and the control unit 132 as shown in FIG. 3, and may also be other circuit structures capable of regulating the first current I2 based on the comparison result of the currents, which is not limited in the embodiment of the present disclosure. Secondly, the quantization module 130 may implement the regulation of the first current I2 in the comparison manner in Formula (3), and may also implement the comparison of the bias current I1 and the clamping branch current I4 and the regulation of the first current I2 in other manners according to the selection of different circuit structures, which is not limited in the embodiment of the present disclosure. Thirdly, the regulation subunit 1322 may be a successive approximation register (SAR) as shown in FIG. 3, and may also be other electronic elements capable of processing the comparison result and generating the logic signal; and the comparison subunit 1321 may be a comparison circuit formed by a comparator Q3 and a sub-circuit Q4 as shown in FIG. 3, and may also be other electronic elements capable of achieving a comparison function, which is not limited in the embodiment of the present disclosure.

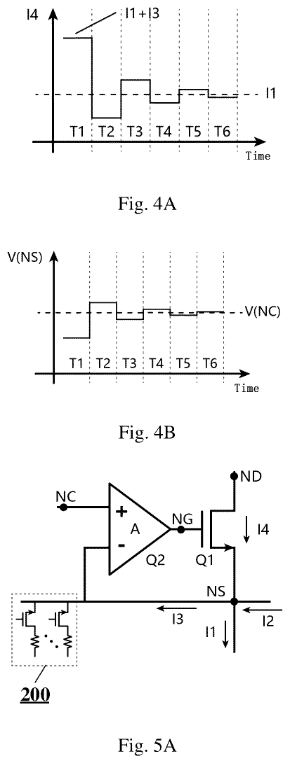

FIG. 4A is a schematic diagram of successive approximation current regulation provided by at least one embodiment of the present disclosure; and FIG. 4B is a schematic diagram of successive approximation voltage regulation provided by at least one embodiment of the present disclosure. For example, FIG. 4A and FIG. 4B respectively show specific implementation examples of current regulation and voltage regulation of the analog-to-digital conversion circuit 100 shown in FIG. 3.

For example, as shown in FIG. 4A, at a moment T1, the first current I2 output by the first current generation unit 131 is equal to 0, and for the clamping point NS, at this moment I4=I1+I3; and that is, when the load circuit 200 works, the load current I3 causes an offset between the clamping branch current I4 and the bias current I1. At this moment (the moment T1), as shown in FIG. 4B, since the gain of the clamping module 110 is limited, there is a larger error in the offset between the voltage V(NS) at the clamping point NS and the clamping reference voltage V(NC), namely, the clamping voltage V(NS).

For example, as shown in FIG. 4A, at a moment T2, the quantization module 130 enables the first current generation unit 131 to generate a first current I2 greater than 0 based on the comparison result of the bias current I1 and the clamping branch current I4 through the above regulation mechanism, thereby reducing the clamping branch current I4, and at this moment I4=I1+I3−I2; further, at a moment T3, the quantization module 130 reduces the first current I2 through the above regulation mechanism, thereby increasing the clamping branch current I4 . . . as the successive approximation regulation process of the quantization module 130 proceeds, the first current I2 generated by the first current generation unit 131 gradually approaches the load current I3, so that the deviation between the clamping branch current I4 and the bias current I1 gradually becomes smaller, and ideally I4=I1 and I2=I3 may be finally achieved, thereby achieving the quantization process.

For example, as shown in FIG. 4B, in the above regulation process, the clamping voltage V(NS) also gradually approaches the clamping reference voltage V(NC), and ideally V(NS)=V(NC) may be finally achieved, so that the clamping tube unit Q1 approaches a state during standard clamping, thereby ensuring the overall quantization accuracy.

In the embodiment of the present disclosure, the quantization module 130 avoids the problems of higher power consumption, area overhead, and more severe noise which may be caused by improving the clamping accuracy and establishment speed of the clamping module 110 through the above regulation process, thereby enabling the analog-to-digital conversion circuit 100 to improve the equivalent clamping accuracy and reducing the noise in the circuit while achieving a high-speed and low-gain clamping function.

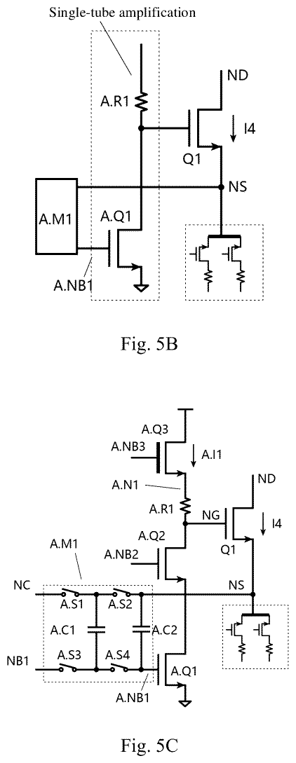

FIG. 5A is a schematic diagram of one example of a clamping module provided by at least one embodiment of the present disclosure; FIG. 5B is a schematic diagram of another example of the clamping module provided by at least one embodiment of the present disclosure; and FIG. 5C is a schematic diagram of yet another example of the clamping module provided by at least one embodiment of the present disclosure.

For example, FIG. 5A shows a specific implementation example of a circuit structure of the clamping module 110 shown in FIG. 3, the specific structure and function thereof are the same as those of the clamping module 110 shown in FIG. 3, and reference may be made to the description in FIG. 3 for details, which will not be described in detail herein. For example, FIG. 5B shows a specific implementation example of a circuit structure of the clamping module shown in FIG. 5A, and FIG. 5C shows a specific implementation example of a circuit structure of the clamping module shown in FIG. 5B.

For example, the clamping amplification gain A of the amplifier unit Q2 in FIG. 5A may be provided by a single-tube amplification structure shown in FIG. 5B. For example, the loop gain is approximately single-tube amplification open-loop gain, a common-source amplifier is formed by A.Q1 and A.R1, and A.M1 is used for cancelling a bias between the amplifier input V(A.NB1) and the voltage V(NS) at the clamping point NS.

For example, a specific implementation example of an amplifier containing an A.M1 structure is as shown in FIG. 5C, and A.M1 is implemented by a switched capacitor bias consisting of A.S1 to A.S4 and A.C1 to A.C2: a loop gain multiplication factor is suppressed by the deviation between the clamping reference voltage V(NC) and the clamping voltage V(NS), thereby enhancing the clamping gain of the source-follower structure formed by the amplifier unit Q1 and the clamping tube unit Q2. For example, adding A.Q2 may enable both a drain of the clamping amplifier input tube A.Q1 and a gate of the clamping tube unit Q1 to be at a suitable level; meanwhile, the amplifier bias current A.I1 is approximately determined by A.Q1, A.Q2, and gate voltages thereof. For example, by adding A.Q3 and controlling the gate voltage A.NB3 of the A.Q3, a supply voltage A.N1 of the common-source structure may be stabilized, thereby suppressing the effect of the supply voltage fluctuation.

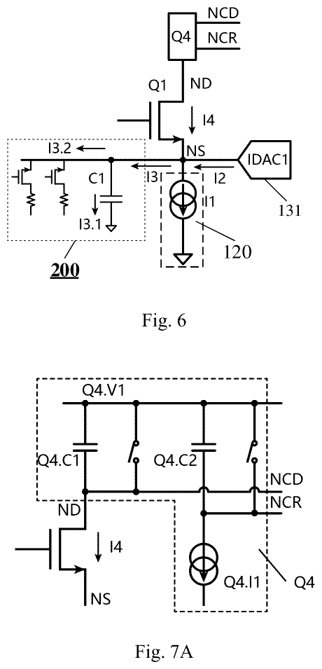

FIG. 6 is a schematic diagram of one example of the effect of parasitic capacitance on current distribution of the analog-to-digital conversion circuit provided by at least one embodiment of the present disclosure. For example, FIG. 6 shows a schematic diagram of a partial circuit structure containing the clamping point NS shown in FIG. 3, and reference may be made to the description in FIG. 3 for details of the specific connection relationship and function implementation, which will not be described in detail herein.

For example, as shown in FIG. 6, the sub-circuit Q4 in the comparison subunit 1321 is used for converting the clamping branch current I4 into the first differential voltage V(NCD) and the second differential voltage V(NCR) to be input into the comparator Q3. For example, the clamping branch current I4 is formed by two parts, in which one part is a part obtained after the cancellation of the first current I2 and the load current I3 (namely, I3-I2), and the other part is the bias current I1. For example, in order that a working point of the clamping tube unit Q1 does not vary too much in the regulation process, the bias current I1 provided by the bias current generation module 120 needs to be greater than the load current I3.

For example, as shown in FIG. 6, in a non-ideal state, parasitic capacitance C1 may exist in a part of the load circuit 200 which is connected to the clamping point NS, while a larger bias current I1 may cause a larger change in the first differential voltage V(NCD), thereby causing an offset in the voltage V(NS) at the clamping point NS; and this voltage variation may cause a charge-discharge current I3.1 to be generated on the parasitic capacitance C1, thereby resulting in a deviation between the load current I3 flowing through the clamping point NS and the actual current I3.2 on the first source line SL<j> in the load circuit 200, thereby introducing a measurement error.

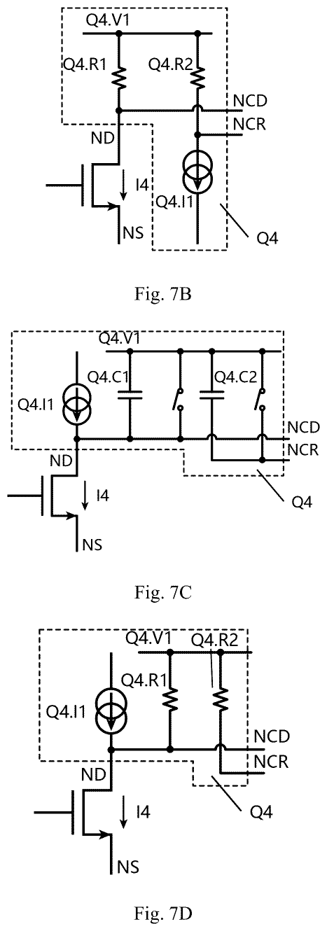

FIG. 7A is a schematic diagram of one example of a comparison subunit provided by at least one embodiment of the present disclosure; FIG. 7B is a schematic diagram of another example of the comparison subunit provided by at least one embodiment of the present disclosure; FIG. 7C is a schematic diagram of yet another example of the comparison subunit provided by at least one embodiment of the present disclosure; and FIG. 7D is a schematic diagram of still yet another example of the comparison subunit provided by at least one embodiment of the present disclosure. For example, FIG. 7A to FIG. 7D show schematic diagrams of specific implementation examples of the circuit structure of the sub-circuit Q4 in the comparison subunit 1321 in FIG. 6.

For example, the examples as shown in FIG. 7A and FIG. 7C are the conversion of the clamping branch current I4 into the first differential voltage V(NCD) and the second differential voltage V(NCR) through an alternating integration-reset process. For example, in FIG. 7A and FIG. 7C, the sub-circuit Q4 includes the capacitance Q4.C1 and Q4.C2 and the current source Q4.I1, and needs to satisfy Q4.C1/I1=Q4.C2/Q4.I1.

For example, the examples as shown in FIG. 7B and FIG. 7D are the conversion of the clamping branch current I4 into the first differential voltage V(NCD) and the second differential voltage V(NCR) through resistive voltage division. For example, in FIG. 7B and FIG. 7D, the sub-circuit Q4 includes the capacitance Q4.R1 and Q4.R2 and the current source Q4.I1, and needs to satisfy Q4.R1*I1=Q4.R2*Q4.I1.

For example, in order to obtain a suitable bias voltage V(ND) to enable the clamping tube unit Q1 to be in a normally working bias state, it is required that Q4.C1 in FIG. 7A is larger or Q4.R1 in FIG. 7B is smaller, so as to avoid an excessive voltage drop of the sub-circuit Q4 itself. For example, in FIG. 7A and FIG. 7B, larger Q4.C1 or smaller Q4.R1 requires a further increase in the bias current I1; however, referring to the above description, for the presence of the parasitic capacitance C1 in the non-ideal state in FIG. 6, the larger bias current I1 may introduce a larger measurement error of the load current I3.

For example, in FIG. 7C and FIG. 7D, the current source Q4.I1 of the same magnitude as the bias current I1 is added at the first node ND to eliminate the effect of the integration of the bias current I1, so that the voltage on the Q4.C1 in FIG. 7C or the voltage on the Q4.R1 in FIG. 7D is ideally determined completely by the part obtained after the cancellation of the first current I2 and the load current I3 (namely, I3-I2); and since the current I3-I2 may gradually approach to 0 in the regulation process of the quantization unit, the magnitude of the bias current I1 is reduced, the fluctuation of the clamping voltage V(NS) is alleviated, and then the charge-discharge current I3.1 generated on the parasitic capacitance C1 is decreased, thereby decreasing the measurement error, and improving the quantization accuracy.

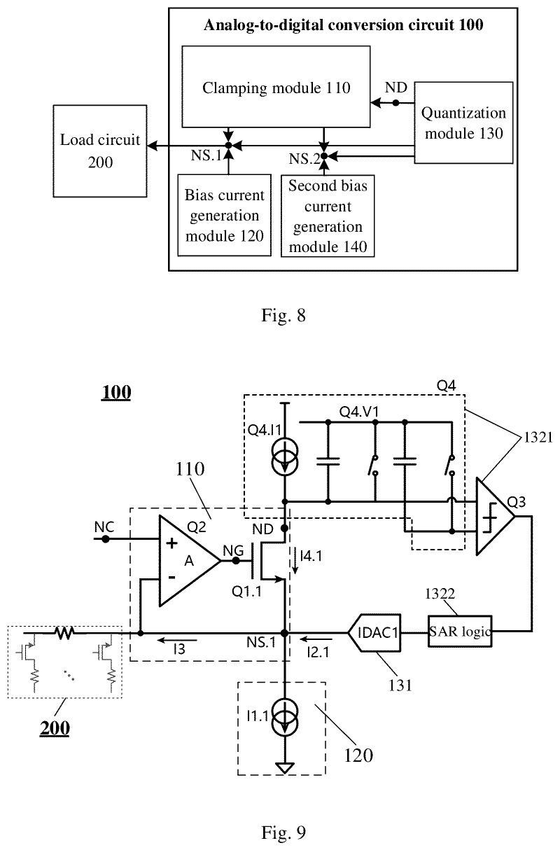

FIG. 8 is another schematic block diagram of the analog-to-digital conversion circuit provided by at least one embodiment of the present disclosure.

For example, in some examples, as shown in FIG. 8, on the basis of FIG. 2, the analog-to-digital conversion circuit 100 may further include a second bias current generation module 140. For example, the second bias current generation module 140 is coupled to the clamping module 110 through a third node NS.2 and configured to generate a second bias current; and the quantization module 130 is further coupled to the clamping module 110 through the third node NS.2, configured to provide a second clamping branch current to the third node NS.2, and further configured to provide a second current to the third node NS.2 and regulate the second current based on the second bias current and a comparison result of the bias current and the clamping branch current.

For example, other structures and functions in FIG. 8 are substantially the same as those of the analog-to-digital conversion circuit 100 in FIG. 2, and reference may be made to the description in FIG. 2 for details, which will not be described in detail herein.

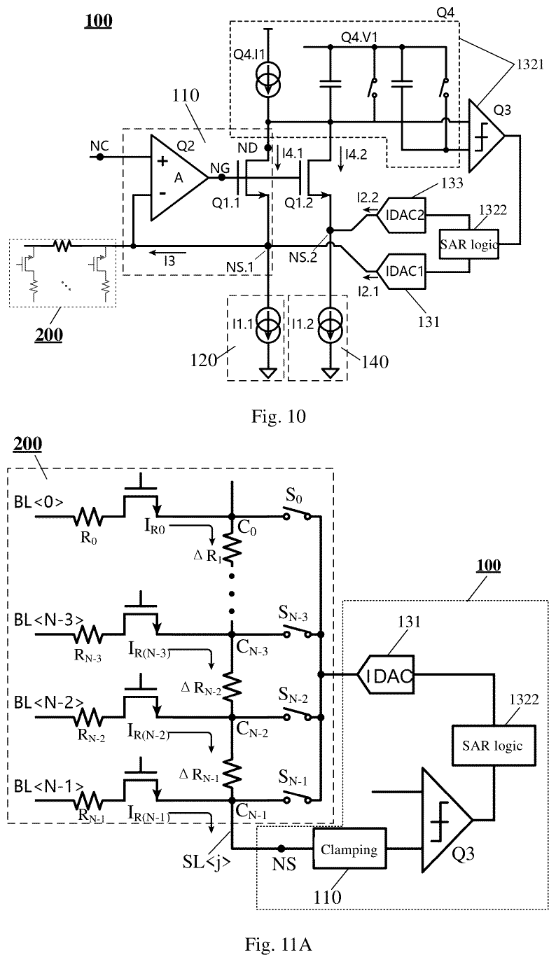

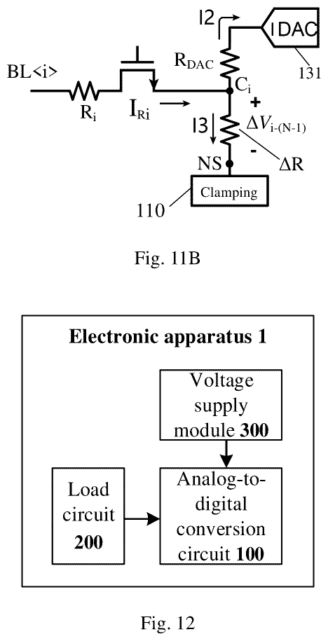

FIG. 9 is a schematic diagram of another example of the analog-to-digital conversion circuit provided by at least one embodiment of the present disclosure; and FIG. 10 is a schematic diagram of yet another example of the analog-to-digital conversion circuit provided by at least one embodiment of the present disclosure.

For example, FIG. 9 shows one specific implementation example of the analog-to-digital conversion circuit 100 shown in FIG. 2 and FIG. 3, namely, the example in FIG. 7C is selected as the circuit structure of the sub-circuit Q4 in the comparison subunit 1321, so that higher quantization accuracy may be achieved; and the sub-circuit Q4 may also be modified with other structures according to the capacitive load conditions and accuracy requirements of the load circuit, which is not limited in the embodiment of the present disclosure. For example, other structures and functions in FIG. 9 are the same as those of the analog-to-digital conversion circuit 100 in FIG. 3, and reference may be made to the description in FIG. 3 for details, which will not be described in detail herein.

For example, FIG. 10 shows one specific implementation example of the analog-to-digital conversion circuit 100 shown in FIG. 8. For example, as shown in FIG. 10, on the basis of FIG. 9, the analog-to-digital conversion circuit 100 may further include a second bias current generation module 140. For example, the second bias current generation module 140 is coupled to the clamping module 110 through a third node NS.2 and configured to generate a second bias current I1.2. For example, the second bias current generation module 140 may be a current source, and may also be other electronic elements capable of providing a bias current, which is not limited in the embodiment of the present disclosure.

For example, as shown in FIG. 10, the clamping module 110 may further include a second clamping tube unit Q1.2. For example, a control terminal of the second clamping tube unit Q1.2 is coupled to an output terminal of the amplifier unit Q2, a first terminal of the second clamping tube unit Q1.2 is coupled to the first node ND, and a second terminal of the second clamping tube unit Q1.2 is coupled to the third node NS.2.

For example, as shown in FIG. 10, the second clamping tube unit Q1.2 may be an N-type transistor, with a first terminal which may be a collector of the transistor, a second terminal which may be an emitter of the transistor, and a control terminal which may be a base of the transistor. For example, the second clamping tube unit may also be electronic elements of other types, such as a metal-oxide semiconductor field effect transistor (MOSFET), a thin film transistor or other three-terminal switch elements; and when the amplifier unit or the second clamping tube unit is the electronic element of other types, other connection manners may be selected according to actual situations, and the type of the second clamping tube and the connection manner thereof are also not limited in the embodiment of the present disclosure.

For example, as shown in FIG. 10, the quantization module 130 is further coupled to the clamping module 110 through the third node NS.2 and configured to provide a second clamping branch current I4.2 to the third node NS.2; in addition, the quantization module 130 further provides a second current I2.1 to the third node NS.2 and regulates the second current I2.1 based on the second bias current I1.2 and a comparison result of the bias current I1.1 and the clamping branch current I4.1.

For example, as shown in FIG. 10, the quantization module 130 further includes a second current generation unit 133. The second current generation unit 133 is configured to generate a second current I2.2, and the control unit 130 is configured to control the second current generation unit 133 to increase the second current I2.2 or decrease the second current I2.2 based on the second bias current I1.2 and a comparison result of the bias current I1 and the clamping branch current I4.1.

It should be noted that the second current generation unit 133 may be a current-mode digital-to-analog converter (IDAC2) as shown in FIG. 10, and may also be other electronic elements capable of generating and regulating the second current I2.2, which is not limited in the embodiment of the present disclosure.

For example, as shown in FIG. 10, a high-order segment branch is formed by the bias current generation module 120, the first current generation unit 131, and the clamping tube unit Q1.1, and a low-order segment branch is formed by the second bias current generation module 140, the first current generation unit 131, and the second clamping tube unit Q1.2. For example, the process of achieving the quantization of the load current I3 by regulating the first current I2.1 through the high-order segment branch is the same as the description in FIG. 3, which will not be described in detail herein; and the regulation of the first current I2.1 is compensated by regulating the second current I2.2 through the low-order segment branch to improve the regulation efficiency.

For example, by taking the regulation process in FIG. 4A as an example, for the example with only the high-order segment branch and no low-order segment branch shown in FIG. 9, from the moment T1 to the moment T2, since the first current I2.1 is generated, the clamping branch current I4.1 is decreased to be smaller than the bias current I1.1, but there is still a larger deviation between the clamping branch current I4.1 and the bias current I1.1, so that in the subsequent regulation process, it is required that the first current generation unit 131 is switched a plurality of times to regulate the output first current I2.1. However, since the clamping voltage V(NS) needs to be reestablished after each switching of the first current generation unit 131, a plurality of switching may take a long switching time.

For example, for the example with both the high-order segment branch and the low-order segment branch shown in FIG. 10, in the process of generating the first current I2.1 for regulation, the second current I2.2 may also be generated to vary the bias voltage V(ND) (namely, the second current I2.2 is directly compensated at the first node ND), so that the deviation between the clamping branch current I4.1 and the bias current I1.1 may be quickly decreased, the number of switching times of the first current generation unit is reduced, and the regulation efficiency is improved.

For example, other structures and functions except for the low-order segment branch in FIG. 10 are the same as those of the analog-to-digital conversion circuit 100 in FIG. 9, and reference may be made to the description in FIG. 9 for details, which will not be described in detail herein.

Moreover, it is noted that without being limited to the embodiment in FIG. 8 or FIG. 10, for example, based on the embodiment shown in FIG. 2, FIG. 3 or FIG. 9, a branch with a similar function may also be added similarly to the case in FIG. 8 or FIG. 10 to further improve the regulation efficiency.

For example, in some examples, the analog-to-digital conversion circuit 100 provided by at least one embodiment of the present disclosure may also be used for decreasing a clamping error of the load circuit. For example, an access point of the quantization module 130 which is accessed to the load circuit may be moved from the clamping point NS to other positions on the first source line SL<j>, and the generated first current I2 is utilized for cancelling the load current I3, so that the effect of the wiring IR drop on the first source line SL<j> may be alleviated.

For example, the load circuit includes a first source line, N resistive devices, and N bit lines. N first terminals of the N resistive devices are respectively connected to the first source line through N connection positions on the first source line, and N second terminals of the N resistive devices are respectively connected to the N bit lines. For example, the clamping module is coupled to the Nth connection position in the N connection positions through the clamping point; the quantization module is coupled to the ith connection position in the N connection positions, configured to provide a first current at the ith connection position, and regulate the first current based on a current on the ith resistive device in the N resistive devices and a load current, so that the load current that is regulated is equal to 0; and herein, N is an integer greater than 1, i=1, 2, . . . , N.

FIG. 11A is a schematic diagram of one example of the analog-to-digital conversion circuit used for decreasing a clamping error of a load circuit provided by at least one embodiment of the present disclosure; and FIG. 11B is a schematic diagram of one example of current distribution of the analog-to-digital conversion circuit when used for decreasing the clamping error of the load circuit provided by at least one embodiment of the present disclosure.

For example, the load circuit 200 in FIG. 11A is, for example, a CIM array as shown in FIG. 1B; and for the analog-to-digital conversion circuit 100 (with a partial structure not shown in the drawings) which is accessed to the load circuit 200 through the clamping point NS and other access points in FIG. 11A, compared with the analog-to-digital conversion circuit 100 in FIG. 3, the difference is merely that the access point of the quantization module 130 which is accessed to the load circuit is moved from the clamping point NS to other positions on the first source line SL<j>, and other structures and functions are substantially the same as those of the analog-to-digital conversion circuit 100 in FIG. 3, which will not be described in detail herein.

For example, as shown in FIG. 11A, the load circuit 200 includes a first source line SL<j>, N resistive devices R₀, R₁ . . . . R_{N-2}, R_{N-1}, and N bit lines BL<0>, BL<1> . . . . BL<N−1>, in which N is a positive integer. For example, the first source line SL<j> is the jth source line in the K columns of source lines in FIG. 1B, in which K is a positive integer, j=0, 1, . . . , K−1.

For example, as shown in FIG. 11A, N first terminals of the N resistive devices are respectively connected to the first source line SL<j> through N connection positions C₀, C₁ . . . . C_{N-1} on the first source line SL<j>, and N second terminals of the N resistive devices are respectively connected to the N bit lines. For example, currents I_{R0}, I_{R1} . . . . I_{R(N-2)}, I_{R(N-1)} respectively flow through the N resistive devices. For example, each resistive device is connected to an adjacent switching element to form a 1T1R memristor unit; and for example, R in 1T1R represents a memristor (such as an RRAM or other resistive devices), and T represents a switching element (such as a transistor or other three-terminal switch elements), which is not limited in the embodiment of the present disclosure.

For example, as shown in FIG. 11A, the clamping module 110 is coupled to the Nth connection position C_{N-1} in the N connection positions through the clamping point NS, and the quantization module 130 (with a partial structure not shown in the drawings) may be coupled to the ith connection position Cᵢ in the N connection positions, in which i=1, 2, . . . , N.

For example, in a non-ideal state, as shown in FIG. 11A, line resistance ΔR₀ (not shown in the drawings), ΔR₁ . . . ΔR_{N-2}, and ΔR_{N-1} may exist on the first source line SL<j>, and a wiring IR drop may be respectively generated on each part of the line resistance, thereby causing a deviation between the current actually flowing into the ADC and an ideal value, and reducing the computational accuracy; and in an ideal state, if the load current I3 on the first source line SL<j> is equal to 0, the wiring IR drops on the N resistive devices are also respectively 0, so that the effect of the wiring IR drops may be reduced.

For example, as shown in FIG. 11A, N switches S₀, S₁ . . . . S_{N-1} are respectively arranged between the first current generation unit 131 in the quantization module 130 and the N connection positions; and when it is required to achieve that the first current generation unit 131 is coupled to the ith connection position Cᵢ, the switch Sᵢ may be closed, while the other switches are kept in an open state. For example, when the first current generation unit 131 is coupled to the ith connection position Cᵢ, the first current generation unit 131 provides a first current I2 at the ith connection position Cᵢ, and the quantization module 130 regulates the first current I2 based on the current I_{Ri} on the ith resistive device Rᵢ in the N resistive devices and the load current I3 on the first source line SL<j> to enable the regulated load current I3 to be equal to 0.

For example, FIG. 11B shows one example of the current distribution of the first current generation unit 131 in FIG. 11A when coupled to the ith connection position Cᵢ.

For example, as shown in FIG. 11B, Rᵢ is the ith resistive device, with a first terminal being connected to the first source line SL<j> through the ith connection position Cᵢ on the first source line SL<j>, and a second terminal being connected to the i^{th} bit line BL<i>; and the current I_{Ri} flows through the ith resistive device Rⱼ. For example, ΔR is a line resistance between the ith connection position Cᵢ and the clamping point NS, ΔV_{N-1} is the wiring IR drop between the ith connection position Cᵢ and the clamping point NS, and R_{DAC} is the parasitic resistance between the first current generation unit 131 and the ith connection position Cᵢ.

For example, as shown in FIG. 11B, when the first current generation unit 131 is coupled to the ith connection position Cᵢ, based on the logic signal generated by the control unit 132 in the quantization module 130, a negative first current I2 generated by the first current generation unit 131 gradually approaches to the current I_{Ri} on the ith resistive device Rᵢ, so that the load current I3 flowing into the clamping point NS on the first source line SL<j> gradually approaches 0; and different connection positions may be selected for access according to different distribution of the load current I3, and flexible cancellation of the load current on the first source line SL<j> may be achieved. Therefore, through the above current regulation and cancellation processes, the wiring IR drops ΔV₀, ΔV₁ . . . ΔV_{N-1} of the line resistance on the first source line SL<j> may also approach 0, thereby alleviating the decrease in the computational accuracy of the ADC caused by the wiring IR drops.

It should be noted that the generation and regulation processes of the first current I2 by the quantization module 130 are the same as the foregoing processes (for example, when the first current I2 is regulated to enable the load current I3 to approach 0, the clamping branch current I4 also approaches to be equal to the bias current I1), and reference may be made to the description in FIG. 2 to FIG. 10 for details, which will not be described in detail herein.

The analog-to-digital conversion circuit provided by the embodiments of the present disclosure optimizes the circuit structure of the ADC, and adopts a completely new clamping quantization mechanism based on the optimized ADC circuit structure, thereby improving the clamping accuracy by utilizing the quantization module and reducing the power consumption and area overhead of the ADC circuit, while achieving a high-speed and low-gain clamping function; in addition, the optimized ADC circuit structure may also be used for adaptively cancelling the computing current on the load circuit, thereby reducing the computing deviation caused by the wiring IR drop and decreasing the effect of parasitic parameters on the load circuit.

FIG. 12 is a schematic diagram of an electronic apparatus provided by some embodiments of the present disclosure.

For example, as shown in FIG. 12, the electronic apparatus 1 includes an analog-to-digital conversion circuit 100, a load circuit 200, and a voltage supply module 300.

For example, the digital conversion circuit 100 may be the analog-to-digital conversion circuit 100 provided by at least one embodiment of the present disclosure. For example, the load circuit 200 may be a memristor unit array, and in some examples, a specific structure of the memristor unit array may be as shown in FIG. 1B; and other array structures may also be selected for the load circuit 200 according to the actual needs, which is not limited in the embodiment of the present disclosure.

For example, the voltage supply module 300 is configured to supply a clamping reference voltage V(NC) to a clamping module 110 in the analog-to-digital conversion circuit 100 through a second node NC. For example, the voltage supply module 300 may be implemented by a digital circuit or an analog circuit, which is not limited in the embodiment of the present disclosure.

For example, reference may be made to the description in any one of the embodiments of the present disclosure for details of the structures, functions, and technical effects of the analog-to-digital conversion circuit 100 and the load circuit 200, which will not be described in detail herein.

For example, the electronic apparatus 1 may be a system for analog Computing In Memory, may also be any device such as a mobile phone, a tablet computer, a notebook computer, an electronic book, a game machine, a television, a digital photo frame, and a navigator, and may also be any combination of the electronic apparatus and hardware, which is not limited in the embodiment of the present disclosure.

It should be noted that for the sake of clarity and brevity, the embodiment of the present disclosure does not give all the constituent units of the electronic apparatus 1. In order to achieve the necessary functions of the electronic apparatus, those skilled in the art may provide and arrange other constituent units which are not shown according to the specific needs, which is not limited in the embodiment of the present disclosure.

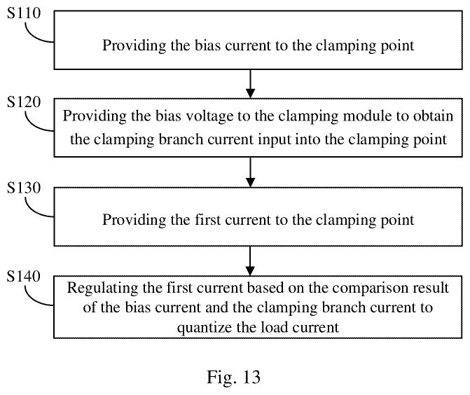

FIG. 13 is a flowchart of an operation method of the analog-to-digital conversion circuit provided by some embodiments of the present disclosure, for example, corresponding to the embodiment shown in FIG. 2.

For example, as shown in FIG. 13, in at least one embodiment of the present disclosure, the operation method of the analog-to-digital conversion circuit 100 includes the steps of S110 to S140:
step S110: providing the bias current to the clamping point;
step S120: providing the bias voltage to the clamping module to obtain the clamping branch current that is input into the clamping point;
step S130: providing the first current to the clamping point; and
step S140: regulating the first current based on the comparison result of the bias current and the clamping branch current to quantize the load current.

For example, in the embodiment, for example, in FIG. 2, in step S110, the bias current generation module 120 is coupled to the clamping module through the clamping point NS and provides the bias current to the clamping point NS; in step S120, the quantization module 130 is coupled to the clamping module through the clamping point NS and the first node ND, and provides the bias voltage to the clamping module through the first node ND to obtain the clamping branch current that is input into the clamping point NS; in step S130, the quantization module 130 provides the first current to the clamping point NS; and in step S140, the quantization module 130 regulates the first current based on the comparison result of the bias current and the clamping branch current to quantize the load current.

In the operation method as shown in FIG. 13, based on the optimized ADC circuit structure in the embodiment, for example, in FIG. 2, a completely new clamping quantization mechanism is adopted, thereby improving the clamping accuracy by utilizing the quantization module and reducing the power consumption and area overhead of the ADC circuit, while achieving a high-speed and low-gain clamping function.

For the present disclosure, the following statements should be noted:

(1) The drawings involve only the structure(s) in connection with the embodiment(s) of the present disclosure, and other structure(s) can be referred to common design(s).

(2) In case of no conflict, features in one embodiment or in different embodiments can be combined to obtain new embodiments.

What have been described above are only specific implementations of the present disclosure, the protection scope of the present disclosure is not limited thereto. Any modifications or substitutions easily occur to those skilled in the art within the technical scope of the present disclosure should be within the protection scope of the present disclosure. Therefore, the protection scope of the present disclosure should be based on the protection scope of the claims.

1. An analog-to-digital conversion circuit, comprising:
a clamping module, coupled to a load circuit through a clamping point, wherein the load circuit provides a load current during working;
a bias current generation module, coupled to the clamping module through the clamping point and configured to provide a bias current to the clamping point; and
a quantization module, coupled to the clamping module through the clamping point and a first node, configured to provide a bias voltage to the clamping module through the first node to obtain a clamping branch current that is input into the clamping point, and further configured to provide a first current to the clamping point and regulate the first current based on a comparison result of the bias current and the clamping branch current to quantize the load current.

2. The analog-to-digital conversion circuit according to claim 1, wherein the clamping module is further configured to receive a clamping reference voltage from a second node, and
the quantization module is further configured to regulate the first current to reduce an offset between a voltage at the clamping point and the clamping reference voltage.

3. The analog-to-digital conversion circuit according to claim 2, wherein the clamping module comprises an amplifier unit and a clamping tube unit,
a first input terminal of the amplifier unit is coupled to the second node, and a second input terminal of the amplifier unit is coupled to the clamping point; and
a control terminal of the clamping tube unit is coupled to an output terminal of the amplifier unit, a first terminal of the clamping tube unit is coupled to the first node, and a second terminal of the clamping tube unit is coupled to the clamping point.

4. The analog-to-digital conversion circuit according to claim 1, wherein the quantization module comprises a first current generation unit and a control unit,
the first current generation unit is configured to generate the first current that is quantized, and
the control unit is configured to control the first current generation unit to increase the first current or decrease the first current based on the comparison result of the bias current and the clamping branch current.

5. The analog-to-digital conversion circuit according to claim 4, wherein the control unit comprises a comparison subunit and a regulation subunit,
the comparison subunit is configured to provide the bias voltage to the clamping module through the first node to obtain the clamping branch current that is input into the clamping point, and further configured to convert the clamping branch current into a first differential voltage and a second differential voltage, and output a comparison result of the first differential voltage and the second differential voltage; and
the regulation subunit is configured to determine the comparison result of the bias current and the clamping branch current based on the comparison result of the first differential voltage and the second differential voltage, and to generate a logic signal based on the comparison result of the bias current and the clamping branch current.

6. The analog-to-digital conversion circuit according to claim 5, wherein the first current generation unit is further configured to increase the first current or decrease the first current based on the logic signal.

7. The analog-to-digital conversion circuit according to claim 5, wherein the comparison subunit comprises a cancellation current source, and
the cancellation current source is configured to generate a cancellation current, wherein the cancellation current is equal to the bias current.

8. The analog-to-digital conversion circuit according to claim 5, wherein the regulation subunit is a successive approximation register.

9. The analog-to-digital conversion circuit according to claim 4, wherein the first current generation unit is a current-mode analog-to-digital converter.

10. The analog-to-digital conversion circuit according to claim 1, further comprising a second bias current generation module,
wherein the second bias current generation module is coupled to the clamping module through a third node and configured to generate a second bias current; and
the quantization module is further coupled to the clamping module through the third node, configured to provide a second clamping branch current to the third node, and further configured to provide a second current to the third node and regulate the second current based on the second bias current and the comparison result of the bias current and the clamping branch current.

11. The analog-to-digital conversion circuit according to claim 10, wherein the clamping module comprises a second clamping tube unit and an amplifier unit, and
a control terminal of the second clamping tube unit is coupled to an output terminal of the amplifier unit, a first terminal of the second clamping tube unit is coupled to the first node, and a second terminal of the second clamping tube unit is coupled to the third node.

12. The analog-to-digital conversion circuit according to claim 10, wherein the quantization module comprises a second current generation unit and a control unit,
the second current generation unit is configured to generate the second current,
the control unit is configured to control the second current generation unit to increase the second current or decrease the second current based on the second bias current and the comparison result of the bias current and the clamping branch current.

13. The analog-to-digital conversion circuit according to claim 1, wherein the load circuit comprises a first source line, N resistive devices and N bit lines, N first terminals of the N resistive devices are respectively connected to the first source line through N connection positions on the first source line, and N second terminals of the N resistive devices are respectively connected to the N bit lines,
the clamping module is coupled to an Nth connection position in the N connection positions through the clamping point, and
the quantization module is coupled to an ith connection position in the N connection positions, and configured to provide the first current at the ith connection position, and regulate the first current based on a current on an ith resistive device in the N resistive devices and the load current to enable a load current that is regulated to be equal to 0,
where N is an integer greater than 1, i=1, 2, . . . N.

14. An electronic apparatus, comprising an analog-to-digital conversion circuit, wherein the analog-to-digital conversion circuit comprises:
a clamping module, coupled to a load circuit through a clamping point, wherein the load circuit provides a load current during working;
a bias current generation module, coupled to the clamping module through the clamping point and configured to provide a bias current to the clamping point; and
a quantization module, coupled to the clamping module through the clamping point and a first node, configured to provide a bias voltage to the clamping module through the first node to obtain a clamping branch current that is input into the clamping point, and further configured to provide a first current to the clamping point and regulate the first current based on a comparison result of the bias current and the clamping branch current to quantize the load current.

15. The electronic apparatus according to claim 14, further comprising a voltage supply module and the load circuit,
wherein the voltage supply module is configured to provide a clamping reference voltage to the clamping module through the second node.

16. The electronic apparatus according to claim 15, wherein the load circuit is a memristor unit array.

17. An operation method of an analog-to-digital conversion circuit, wherein the analog-to-digital conversion circuit comprises:
a clamping module, coupled to a load circuit through a clamping point, wherein the load circuit provides a load current during working;
a bias current generation module, coupled to the clamping module through the clamping point and configured to provide a bias current to the clamping point; and
a quantization module, coupled to the clamping module through the clamping point and a first node, configured to provide a bias voltage to the clamping module through the first node to obtain a clamping branch current that is input into the clamping point, and further configured to provide a first current to the clamping point and regulate the first current based on a comparison result of the bias current and the clamping branch current to quantize the load current,
wherein the method comprises:
providing the bias current to the clamping point;
providing the bias voltage to the clamping module to obtain the clamping branch current that is input into the clamping point;
providing the first current to the clamping point; and
regulating the first current based on the comparison result of the bias current and the clamping branch current to quantize the load current.

18. The analog-to-digital conversion circuit according to claim 2, wherein the quantization module comprises a first current generation unit and a control unit,
the first current generation unit is configured to generate the first current that is quantized, and
the control unit is configured to control the first current generation unit to increase the first current or decrease the first current based on the comparison result of the bias current and the clamping branch current.

19. The analog-to-digital conversion circuit according to claim 6, wherein the comparison subunit comprises a cancellation current source, and
the cancellation current source is configured to generate a cancellation current, wherein the cancellation current is equal to the bias current.

20. The analog-to-digital conversion circuit according to claim 11, wherein the quantization module comprises a second current generation unit and a control unit,
the second current generation unit is configured to generate the second current,
the control unit is configured to control the second current generation unit to increase the second current or decrease the second current based on the second bias current and the comparison result of the bias current and the clamping branch current.
